(19) United States
(12) Patent Application Publication
(10) Pub. No.: US 2009/0116937 A1
(43) Pub. Date: May 7, 2009

(54) STORAGE APPARATUS AND FILTER MODULE THEREIN

(76) Inventor: Sheng-Hung WANG, Shulin City (TW)

Correspondence Address: SINORICA, LLC, 528 FALLSGROVE DRIVE, ROCKVILLE, MD, 20850, US

(21) Appl. No.: 12/180,570

(22) Filed: Jul. 28, 2008

(30) Foreign Application Priority Data
Nov. 5, 2007 (TW) 096219274

(51) Int. Cl. H01L 21/677

(52) U.S. Cl. 414/217

(57) ABSTRACT

The present invention provides a storage apparatus, ex. reticle pod, FOUP, FOSB or any kind of wafer pod, for storing a semiconductor element, ex. wafer, or a reticle and having a filter module therein. The storage apparatus is composed of a first cover and a second cover, which are assembled together to form an inner space therebetween for accommodating a reticle or a semiconductor element. The second cover of the storage apparatus comprises at least one aperture for communicating the inner space and an exterior of the storage apparatus and a filter module for covering the aperture.

### BACKGROUND OF THE INVENTION

1. Technical Field

The present invention relates to storage apparatuses, ex. reticle pod, FOUP, FOSB or any kind of wafer pod, for storing semiconductor element, ex. wafer, or reticle and, more particularly, to a storage apparatus for storing a semiconductor element or a reticle and having a filter module therein.

2. Description of Related Art

In the rapidly developing semiconductor technology, optical lithography plays an important role and wherever pattern definition is conducted, optical lithography is requisite. As to the application of optical lithography relating to semiconductors, a designed circuit pattern is used to produce a light-transparent reticle. Basing on the principle of exposure, after a light passes through the reticle and projects on a silicon wafer, the circuit pattern formed on the reticle can be exposed onto the silicon wafer. Since any dust (such as particles, powders or an organic matter) can adversely affect the quality of such projected pattern, the reticle used to produce the pattern on the silicon wafers is required with absolute cleanness. Thus, clean rooms are typically employed in general wafer processes for preventing particles in the air from defiling reticles and wafers. However, absolute dustless environment is inaccessible even in known clean rooms.

Hence, storage apparatuses that facilitate preventing defilement are implemented in current semiconductor processes for the purpose of storage and transportation of reticles so as to ensure cleanness of the reticles. When such storage apparatuses accommodate reticles in semiconductor processes, the reticles can be isolated from the atmosphere when being transferred and conveyed between stations, so as to be secured from defilement caused by impurities that induce deterioration of the reticles. Similarly, when storage apparatuses accommodate semiconductor elements in semiconductor processes, the semiconductor elements can be isolated from the atmosphere when being transferred and conveyed between stations, so as to be secured from defilement caused by impurities that induce deterioration. Further, in advanced semiconductor factories, the cleanliness of storage apparatuses is required to meet Standard Mechanical Interface (SMIF), namely superior to Class 1. One solution for achieving the required cleanliness is to fill gas into the storage apparatuses.

However, for enhancing the yield of products and reducing manufacturing costs, in addition to meeting the required cleanliness, defilement that is brought to reticles by external gases has to be precluded. Besides the atmosphere, there are still two major resources of the gases that may cause defilement to reticles. One of them is outgasing generated by storage apparatuses themselves that are made of macromolecular materials. The other is vapourised gas generated by trace chemical solutions remained on the surfaces of the storage apparatuses. These unexpected gases can cause foggy surfaces of reticles or semiconductor elements that render the reticles or semiconductor elements becoming rejects resulting in wasted manufacturing costs. While filling gas into such storage apparatuses is also a solution for preventing foggy surfaces thereof, it is an important task to ensure the cleanliness of the filled gas.

Therefore, the present invention provides a storage apparatus for storing a semiconductor element or a reticle and having a filter module o improve the current technology.

### SUMMARY OF THE INVENTION

To remedy the problem of the prior arts, the present invention provides a storage apparatus, ex. reticle pod, FOUP, FOSB or any kind of wafer pod, for storing a semiconductor element, ex. wafer, or a reticle and having a filter module therein. The storage apparatus is composed of a first cover and a second cover, which are assembled together to form an inner space therebetween for accommodating a reticle or a semiconductor element. The second cover of the storage apparatus comprises at least one aperture for communicating the inner space and an exterior of the storage apparatus and a filter module for covering the aperture. The filter module is constructed from a filter and a fixing element. According to one preferred embodiment of the present invention, the filter module further comprises a first portion, a second portion, a fixing element and a filter, wherein the first portion has a through hole and a retaining mechanism while the second portion has a through and an engaging mechanism. The filter is settled on the first portion or the second portion and is fixed by the fixing element.

Thereupon, it is one objective of the present invention to provide a storage apparatus for storing a semiconductor element or a reticle and having a filter module that facilitates filtering dust in air so as to protect the reticles or the semiconductor element accommodated therein from being defiled.

It is another objective of the present invention to provide a storage apparatus for storing a semiconductor element or a reticle and having a filter module that facilitates filtering dust in air so as to maintain cleanliness therein.

### BRIEF DESCRIPTION OF THE DRAWINGS

The invention as well as a preferred mode of use, further objectives and advantages thereof, will best be understood by reference to the following detailed description of an illustrative embodiment when read in conjunction with the accompanying drawings, wherein:

FIG. 1 is a perspective view of a storage apparatus for storing a semiconductor element or a reticle of the present invention;

FIGS. 2A to 2D provide exemplificative structures of a filter and a fixing element of the storage apparatus of the present invention;

FIGS. 3A to 3D provide alternative structures of a filter and a fixing element of the storage apparatus of the present invention;

FIGS. 4A to 4C provide alternative structures of the filter and the fixing element of the storage apparatus of the present invention;

FIGS. 5A to 5D provide exemplificative configurations of the filter module and the storage apparatus of the present invention;

FIG. 6 is an exploded view of the filter module of the present invention;

FIGS. 7A to 7F provide exemplificative configurations of the fixing element and filter of the filer module of the present invention;

FIGS. 8A to 8C provide exemplificative configurations of the filter, fixing element and a first portion of the filer module of the present invention; and

FIGS. 9A to 9F provide exemplificative configurations of support segments of the first portion and a second portion of the present invention.

### DETAILED DESCRIPTION OF THE PREFERRED EMBODIMENT

While the present invention discloses a storage apparatus, ex. reticle pod, FOUP, FOSB or any kind of wafer pod, for storing a semiconductor element, ex. wafer, or a reticle and having a filter module, it is to be stated first of all that the detailed manufacturing or processing procedures of the disclosed storage apparatus relay on known technology and need not be discussed at length herein. Meantime, while the accompanying drawings are provided for purpose of illustration, it is to be understood that the components and structures therein need not to be made in scale.

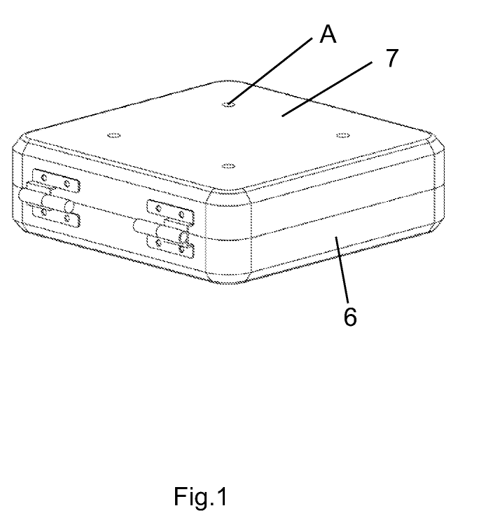

Please refer to FIG. 1 for a perspective view of a storage apparatus, ex. reticle pod, FOUP, FOSB or any kind of wafer pod, for storing a semiconductor element, ex. wafer, or a reticle according to the present invention. The storage apparatus comprises a first cover 6 and a second cover 7 which are assembled to form an inner space therebetween for accommodating a semiconductor element or a reticle. The second cover 7 comprises at least one aperture A for communicating the inner space and an exterior of the storage apparatus.

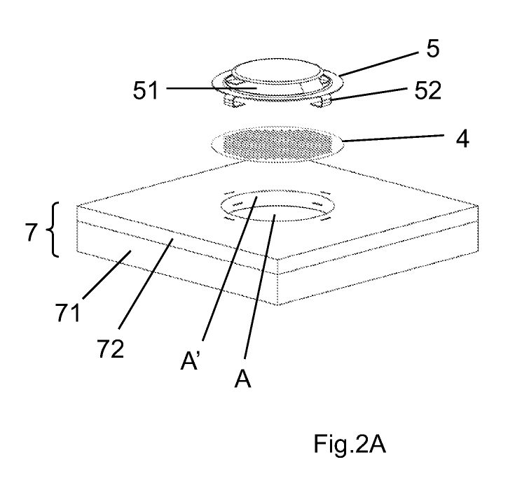

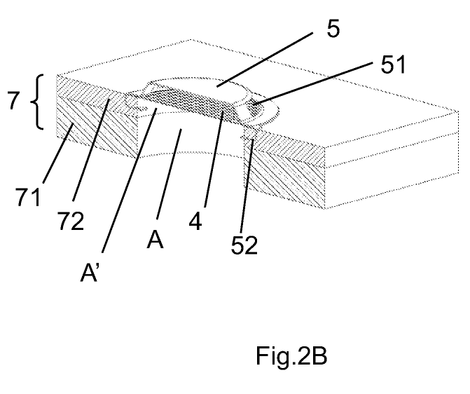

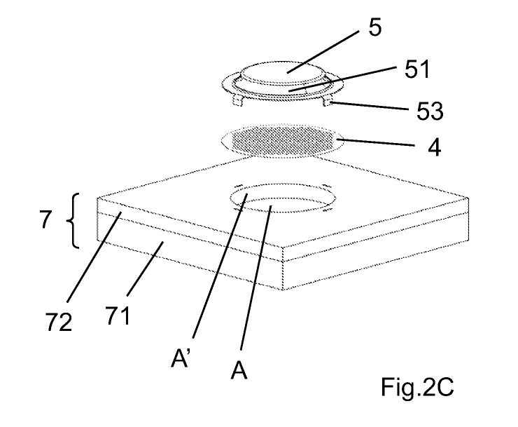

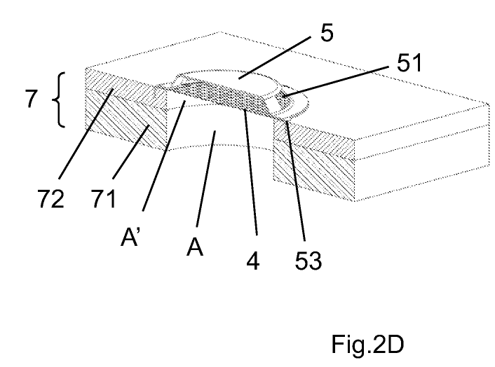

Now referring to FIGS. 2A to 2D, the second cover 7 of the disclosed storage apparatus comprises a body 71 and a plate 72. The at least one aperture A is provided on the body 71 and at least one aperture A′ is provided on the plate 72 positionally corresponding to the body 71. The apertures A and A′ of the body 71 and the plate 72 are communicated to each other for ventilation. Then the filter 4 is deposited on the plate 72 to cover the aperture A′ for filtering the impurities in the air passing therethrough. Further, a fixing element 5 is settled on the filter 4 and connected to the plate 72 so as to fix the filter 4. The fixing element 5 is also equipped with at least one venthole 51 for ventilation. FIG. 2A is an exploded view showing the components while FIG. 2B is a sectional view of the assembled components of the second cover 7. Therein, the fixing element 5 has elongate U-shaped pins 52 for engaging with the plate 72. However, the fixing element 5 may be fastened to the plate 72 with T-shaped pins 53, as shown in FIGS. 2C and 2D.

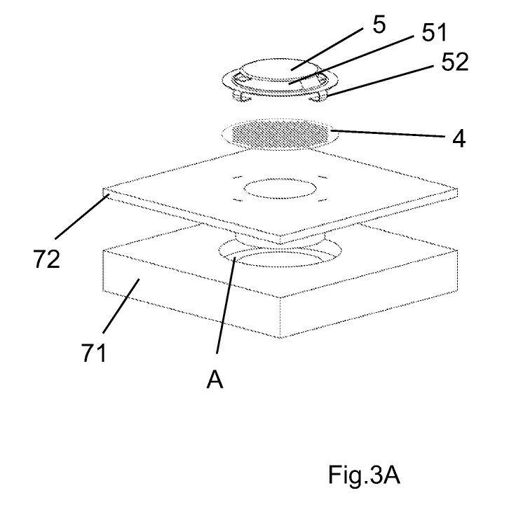

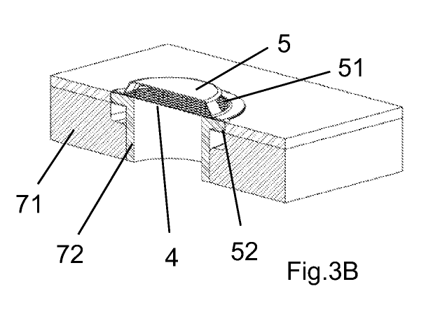

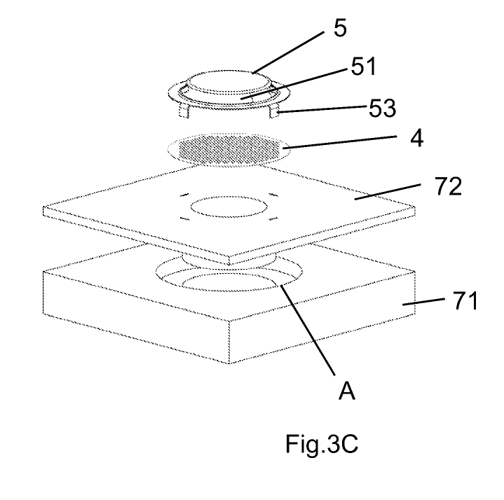

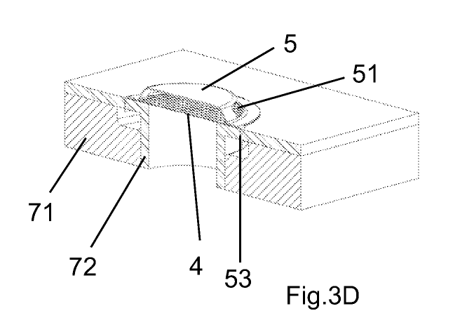

Moreover, referring to FIGS. 3A to 3D, the plate 72 may extend into the aperture A of the body 71 to form a hole for ventilation. Therein, according to FIGS. 3A and 3B, the fixing element 5 is coupled with the plate 72 with the U-shaped pins 52, while in FIGS. 3C and 3D, the fixing element 5 is coupled with the plate 72 with the T-shaped pins 53.

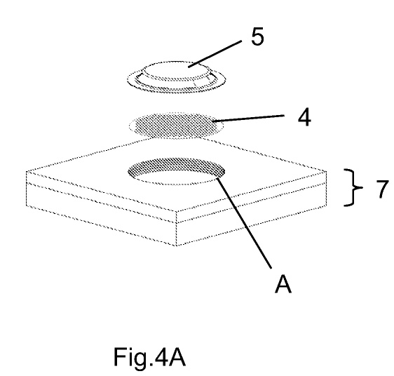

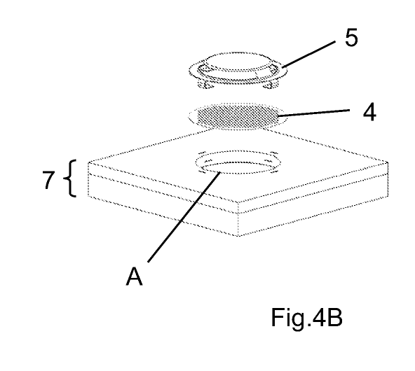

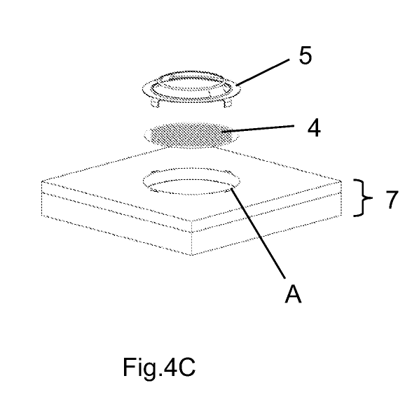

While the plate 72 may or may not extend to the body 71 and the fixing element 5 may be coupled with the plate 72 by any of the above-mentions configuration, the fixing element 5, the plate 72 and the filter 4 may be configured in various manners. Refer to FIGS. 4A to 4C. In FIG. 4A, the fixing element 5 covers the plate 72 for fixing the filter 4. Or, as shown in FIGS. 4B and 4C, the fixing element 5 is coupled with the plate 72. The fixing element 5 may substantially cover the filter 4, as shown in FIGS. 4A and 4B. Alternatively, according to FIG. 4C the fixing element 5 just frame the filter 4. All these modifications can be implemented according to a user's needs.

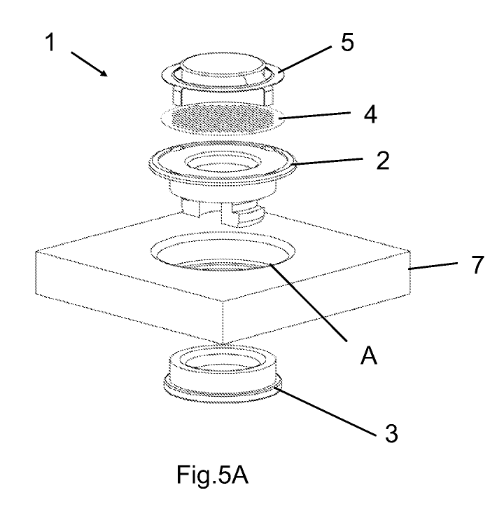

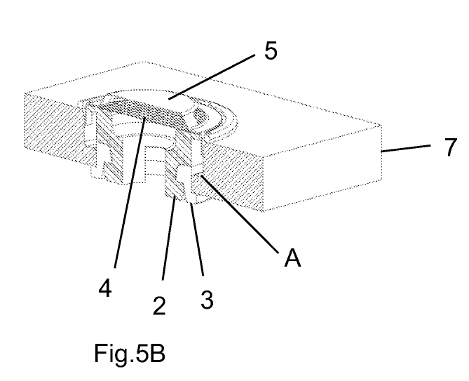

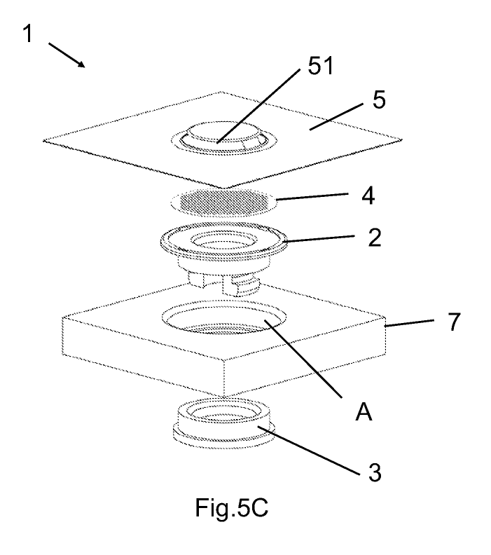

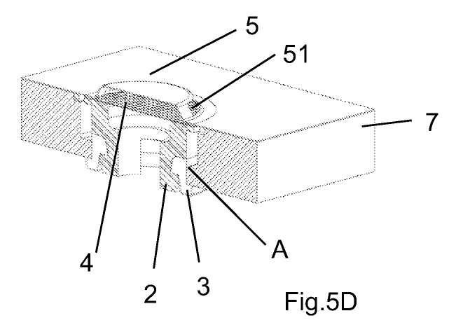

Now referring to FIGS. 5A to 5D, more embodiments of the disclosed storage apparatus are provided. Therein, the second cover 7 has at least one aperture A, and the filter module 1 is combined with the aperture A of the second cover 7. The filter module 1 is composed of a first portion 2, a second portion 3, a filter 4 and a fixing element 5. According to the embodiment shown in FIG. 5A, the fixing element 5 is an independent component and settled on the first portion 2 or the second portion 3 (a similar embodiment where fixing element 5 is settled on the second portion 3 is not shown in the present drawing) for fixing the fixing element 4, while a sectional view of such configuration is provided in FIG. 5B. According to the embodiment shown in FIG. 5C, the fixing element 5 is a plate that substantially covers the surface of the second cover 7 facing the inner space and comprises at least one venthole 51 at a position corresponding to the filter 4 for ventilation, while a sectional view of such configuration is provided in FIG. 5D.

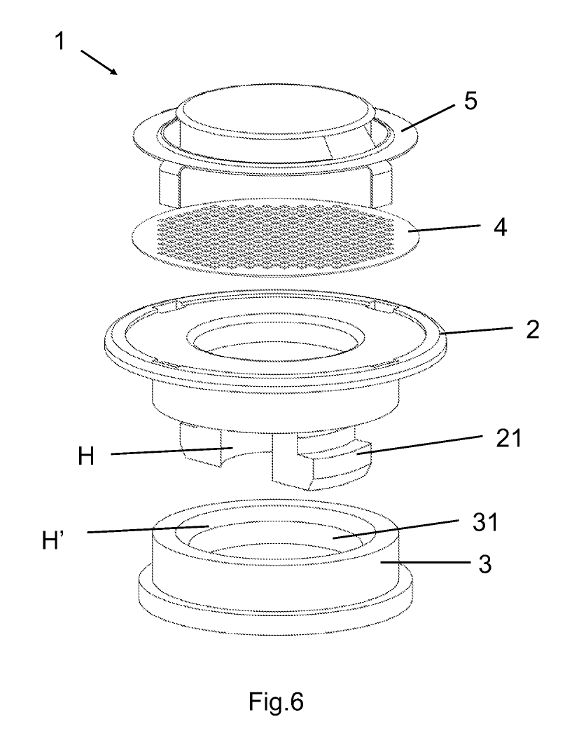

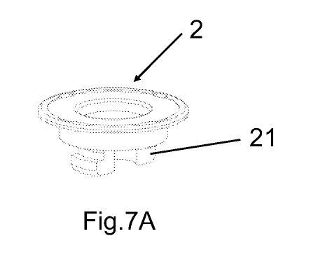

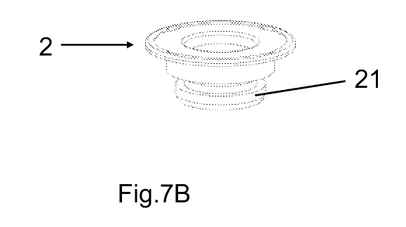

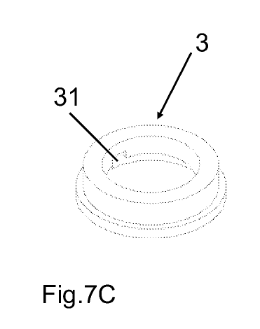

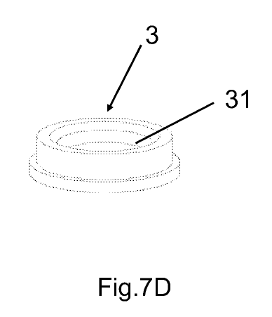

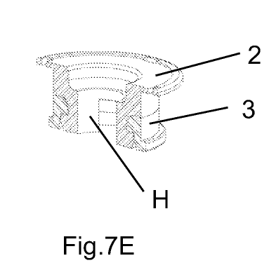

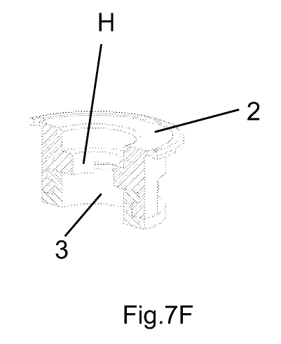

Please refer to FIG. 6 for an exploded view of the filter module 1 according to the embodiments depicted in FIGS. 5A or 5B. The filter module 1 is composed of a first portion 2, a second portion 3, the filter 4 and the fixing element 5. A through hole H is formed at the first portion 2 and another through hole H′ is formed on the second portion 3 so that when the first portion 2 and the second portion 3 are combined mutually, the two through holes H and H′ are integrated as one through hole for allowing air to pass therethrough. Therein, the first portion 2 comprises a retaining mechanism 21 for being coupled with an engaging mechanism 31 of the second portion 3. Exemplificative structures of the first portion 2 and the second portion 3 are shown in FIGS. 7A through 7D. The retaining mechanism 21 may be at least a pair of hooks, as provided in FIG. 7A or an annular flange, as shown in FIG. 7B while the engaging mechanism 31 may be at least a pair of recesses, as provided in FIG. 7C or an annular groove, as shown in FIG. 7D, as long as the retaining mechanism 21 and the engaging mechanism 31 can be coupled mutually.

While the retaining mechanism 21 may be a pair of hooks or an annular flange, the engaging mechanism 31 is at least a pair of recesses or an annular groove for coupling the retaining mechanism 21. As to the configuration of the coupled retaining mechanism 21 and engaging mechanism 31, in FIG. 7E, the retaining mechanism 21 is combined to an inner periphery of the second portion 3 facing the through hole H. Alternatively, in FIG. 7F, the retaining mechanism 21 is combined to an outer periphery of the second portion 3 reverse to the inner periphery.

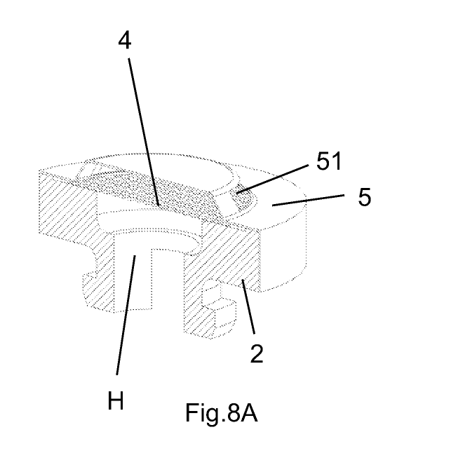

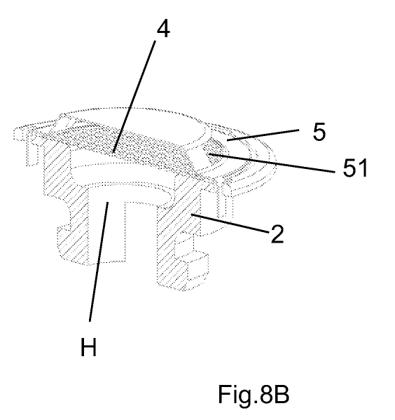

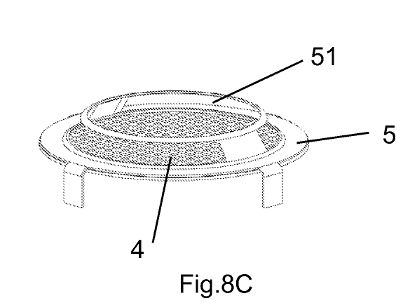

When the first portion 2 and the second portion 3 are combined, the filter 4 may cover the through hole H of the first portion 2 or the second portion 3 so that when air passes through the through hole H, the filter 4 can filter dust in the air. Then the filter 4 is fixed to the first portion 2 or the second portion 3 by the fixing element 5. The fixing element 5 may enclose the first portion 2 or the second portion 3, as shown in FIG. 8A, so as to achieve the purpose of fixing the filter 4. Alternatively, the fixing element 5 may be engaged on the first portion 2 or the second portion 3, as shown in FIG. 8B. The fixing element 5 may substantially cover the filter 4, as shown in FIG. 8A or 8B, or may just frame the filter 4, as shown in FIG. 8C. All these modifications can be implemented according to a user's needs. Properly, the fixing element 5 has at least one venthole 51 for allowing air to pass therethrough.

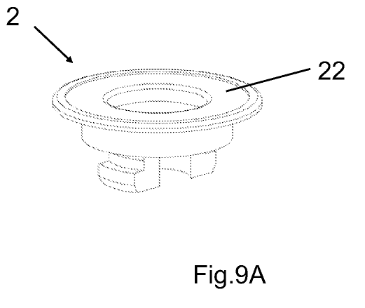

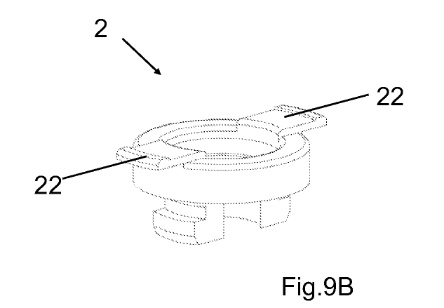

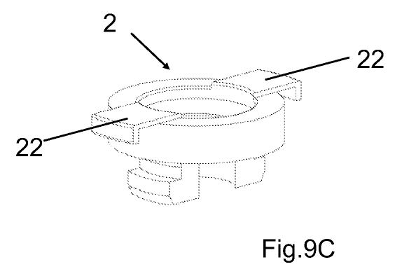

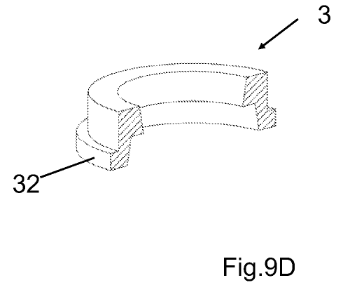

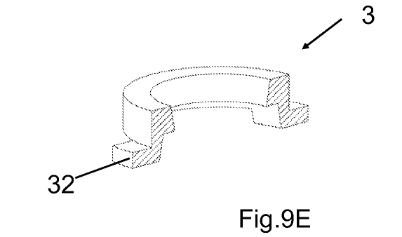

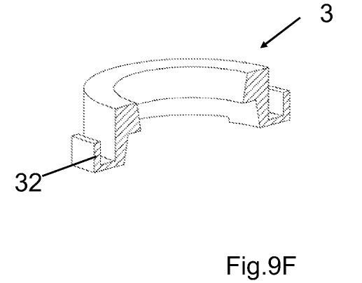

Further, as the filter module 1 is equipped to the storage apparatus, ex. reticle pod, FOUP, FOSB or any kind of wafer pod, for storing a semiconductor element, ex. wafer, or a reticle, to better fix the filter module 1 to the storage apparatus, support segments 22, 32 may be provided on the first portion 2 and the second portion 3. The support segment 22 of the first portion 2 may be formed as an annular flange (as shown in FIG. 9A), at least a projecting pin (as shown in FIG. 9B), or at least a hooked pin (as shown in FIG. 9C). The support segment 23 of the second portion 3 may be formed as an annular flange (as shown in FIG. 9D), at least a projecting pin (as shown in FIG. 9E), or at least a hooked pin (as shown in FIG. 9F). Other modifications can be also implemented for fixing the filter module 1 to the storage apparatus better.

Although the particular embodiments of the invention have been described in detail for purposes of illustration, it will be understood by one of ordinary skill in the art that numerous variations will be possible to the disclosed embodiments without going outside the scope of the invention as disclosed in the claims.

What is claimed is:

1. A filter module deposited in storage apparatus, said filter module comprising,
a first portion, having a through hole and a retaining mechanism;
a second portion, having a through hole positionally corresponding to said through hole of said first portion, and an engaging mechanism for being coupled with said retaining mechanism of said first portion;
a filter, deposited on said first portion or said second portion for covering said through hole; and
a fixing element, for fixing said filter on said first portion or said second portion.

2. The filter module according to claim 1, wherein said fixing element engages on or encloses said first portion or said second portion.

3. The filter module according to of claim 1, wherein said fixing element substantially covers or frames said filter.

4. The filter module according to claim 1, wherein said fixing element has at least one venthole.

5. The filter module according to claim 1, wherein said retaining mechanism is at least a hook.

6. The filter module according to claim 5, wherein said engaging mechanism is a recess or an annular groove for being coupled with said hook so as to combine said first portion and said second portion.

7. The filter module according to claim 5, wherein said hook is shaped as at least a pair of hooks or an annular flange.

8. The filter module according to claim 5, wherein said hook is coupled with an inner periphery of said second portion facing said through hole or coupled with an outer periphery of said second portion.

9. The filter module according to claim 1, wherein said first portion further comprises a support segment.

10. The filter module according to claim 1, wherein said second portion further comprises a support segment.

11. The filter module according to claim 9, wherein said support segment of said first portion further is an annular flange, at least one projecting pin or at least one hooked pin.

12. The filter module according to claim 10, wherein said support segment of said second portion further is an annular flange, at least one projecting pin or at least one hooked pin.

13. A storage apparatus for storing a semiconductor element or a reticle, comprising:
a first cover;
a second cover for being assembled with said first cover to form an inner space for accommodating said semiconductor element or said reticle and comprising at least one aperture, and
a filter module deposited on said second cover and combined with said aperture of said second cover, in which said filter module comprises:
a first portion, having a through hole and a retaining mechanism;
a second portion, having a through hole positionally corresponding to said through hole of said first portion, and having an engaging mechanism for being coupled with said retaining mechanism of said first portion;
a filter, deposited on said first portion or said second portion for covering said through hole; and
a fixing element, for fixing said filter on said first portion or said second portion.

14. The storage apparatus according to claim 13, wherein said fixing element is a plate and substantially covers a surface of said second cover facing said inner space.

15. The storage apparatus according to claim 13, wherein said first portion of said filter module further comprises a support segment for fixing said first portion to said second cover.

16. The storage apparatus according to claim 13, wherein said second portion of said filter module further comprises a support segment for fixing said second portion to said second cover.

17. The storage apparatus according to claim 13, wherein said first portion of said filter module further comprises a support segment having a diameter greater than a diameter of said aperture of said second cover.

18. The storage apparatus according to claim 13, wherein said second portion of said filter module further comprises a support segment having a diameter greater than a diameter of said aperture of said e second cover.

19. A storage apparatus for storing a semiconductor element or a reticle, comprising:
a first cover;
a second cover for being assembled with said first cover to form an inner space for accommodating said semiconductor element or said reticle and comprising
a body, having at least one aperture, and
a plate, deposited on said body and facing said inner space, and having an aperture positionally corresponding to said aperture of said body;
a filter, deposited on said plate and covering said aperture of said plate; and
a fixing element, for fixing said filter on said plate.

20. The storage apparatus according to claim 19, wherein said fixing element is engages on or encloses said plate.
